(19) United States
(12) Patent Application Publication
(10) Pub. No.: US 2014/0253350 A1
(43) Pub. Date: Sep. 11, 2014

(54) DIGITAL/ANALOG CONVERTER CIRCUIT

(71) Applicant: KABUSHIKI KAISHA TOSHIBA, Tokyo (JP)

(72) Inventor: Shigeo Imai, Chiba-Shi (JP)

(73) Assignee: KABUSHIKI KAISHA TOSHIBA, Tokyo (JP)

(21) Appl. No.: 14/152,051

(22) Filed: Jan. 10, 2014

(30) Foreign Application Priority Data
Mar. 11, 2013 (JP) 2013-048105

(51) Int. Cl. H03M 1/06

(52) U.S. Cl. CPC H03M 1/0624
USPC 341/118

(57) ABSTRACT

The digital/analog converter circuit includes a digital/analog converting unit that receives a digital signal and outputs an output current to an output terminal in response to the digital signal. The digital/analog converter circuit includes an error current detecting unit that outputs a detection signal to the digital/analog converting unit, the detection signal correcting the output current.

### CROSS-REFERENCE TO RELATED APPLICATION

This application is based upon and claims the benefit of priority from the prior Japanese Patent Application No. 2013-048105, filed on Mar. 11, 2013, the entire contents of which are incorporated herein by reference.

### BACKGROUND

1. Field

Embodiments of the present invention relate to digital/analog converter circuits.

2. Background Art

Conventionally, a digital/analog converter circuit having prepared larger current source transistors than others compensate for current reduction by a channel length modulation effect to obtain higher linearity.

Unfortunately, the digital/analog converter circuit cannot make a sufficient correction to manufacturing process variations and temperature fluctuations.

### BRIEF DESCRIPTION OF THE DRAWINGS

FIG. 1 is a figure showing a configuration example of a digital/analog converter circuit 100 according to the first embodiment;

FIG. 2 is a figure showing a configuration example of a digital/analog converter circuit 200 according to the second embodiment;

FIG. 3 is a figure showing an example of the relationship between the digital signal DIN of the digital/analog converter circuit 200 in FIG. 2 and an output voltage VOUTP that is an analog signal;

FIG. 4 is a figure showing a configuration example of a digital/analog converter circuit 300 according to the third embodiment;

FIG. 5 is a figure showing a configuration example of a digital/analog converter circuit 400 according to the fourth embodiment; and

FIG. 6 is a figure showing a configuration example of a digital/analog converter circuit 500 according to a fifth embodiment.

### DETAILED DESCRIPTION

A digital/analog converter circuit according to an embodiment includes a digital/analog converting unit that receives a digital signal and outputs an output current to an output terminal in response to the digital signal. The digital/analog converter circuit includes an error current detecting unit that outputs a detection signal to the digital/analog converting unit so as to correct the output power.

The digital/analog converting unit includes a first conversion current source that outputs a first conversion current with a first end connected to a power supply. The digital/analog converting unit includes a second conversion current source that outputs a second conversion current with a first end connected to the power supply, the second conversion current being obtained by performing a current mirror operation on the first conversion current. The digital/analog converting unit includes a first conversion switch circuit that controls electrical connection between a second end of the first conversion current source and the output terminal based on the digital signal. The digital/analog converting unit includes a second conversion switch circuit that controls electrical connection between a second end of the second conversion current source and the output terminal based on the digital signal. The digital/analog converting unit includes a first correction current source with a first end connected to the power supply, the first correction current source outputting a first correction current in response to the detection signal. The digital/analog converting unit includes a second correction current source with a first end connected to the power supply, the second correction current source outputting a second correction current in response to the detection signal. The digital/analog converting unit includes a first correction switch circuit that controls electrical connection between a second end of the first correction current source and the output terminal in synchronization with the first conversion switch circuit. The digital/analog converting unit includes a second correction switch circuit that controls electrical connection between a second end of the second correction current source and the output terminal in synchronization with the second conversion switch circuit.

A first embodiment will describe a basic configuration of a digital/analog converter circuit. Second to fifth embodiments will specifically describe the configuration and operating characteristics of the digital/analog converter circuit. The embodiments will be discussed below with reference to the accompanying drawings.

### First Embodiment

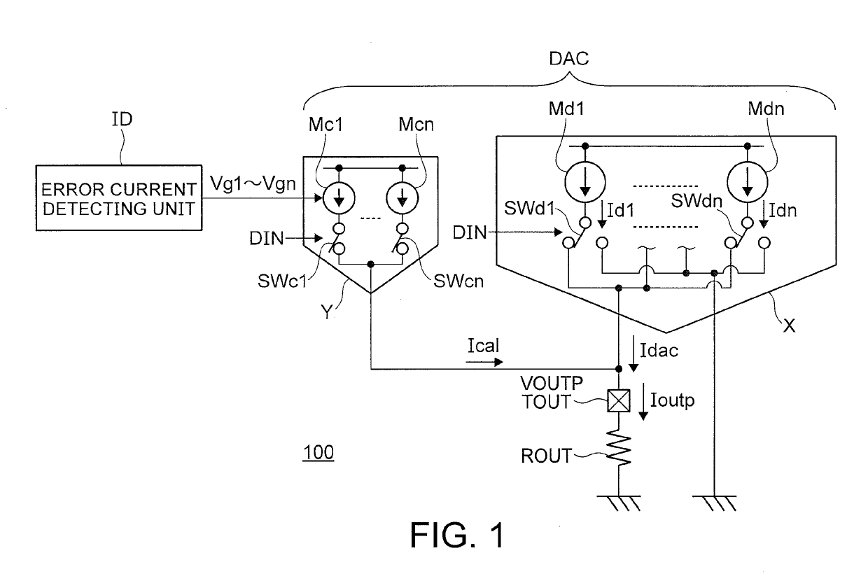

FIG. 1 illustrates a configuration example of a digital/analog converter circuit 100 according to the first embodiment.

As shown in FIG. 1, the digital/analog converter circuit 100 includes a digital/analog converting unit DAC and an error current detecting unit ID.

The error current detecting unit ID outputs detection signals Vg1 to Vgn to the digital/analog converting unit DAC to correct an output current Ioutp.

The digital/analog converting unit DAC receives a digital signal DIN and outputs the output current Ioutp to an output terminal TOUT in response to the digital signal DIN.

As shown in FIG. 1, the digital/analog converting unit DAC includes, for example, a main unit X, a correcting section Y, and an output resistor ROUT.

The main unit X includes a plurality of conversion current sources Md1 to Mdn (n: an integer of at least 2) and a plurality of (n) conversion switch circuits SWd1 to SWdn. In FIG. 1, the conversion current sources Md2 to Mdn−1 and the conversion switch circuits SWd2 to SWdn−1 are omitted for the sake of simplicity.

The main unit X receives the digital signal DIN and outputs a current Idac to the output terminal TOUT in response to the digital signal DIN.

The correcting section Y includes a plurality of (n) correction current sources Mc1 to Mcn and a plurality of (n) correction switch circuits SWc1 to SWcn. In FIG. 1, the correction current sources Mcg to Mcn−1 and the conversion switch circuits SWc2 to SWcn−1 are omitted for the sake of simplicity.

The correcting section X receives the digital signal DIN and outputs a current Ical to the output terminal TOUT in response to the digital signal DIN and the detection signals Vg1 to Vgn.

The output resistor ROUT is connected between the output terminal TOUT and the ground.

The passage of the output current Ioutp (the current Idac+the current Ical) through the output resistor ROUT outputs an output voltage (analog signal) VOUTP from the output terminal TOUT.

In this configuration, one end of the first conversion current source Md1 is connected to a power supply to output a first conversion current Id1.

One end of the n-th conversion current source Mdn is connected to the power supply so as to output an n-th conversion current Idn obtained by performing a current mirror operation on the first conversion current Id1.

The first conversion switch circuit SWd1 is disposed between the other end of the first conversion current source Md1 and the output terminal TOUT to control electrical connection between the first conversion current source Md1 and the output terminal TOUT based on the digital signal DIN.

In the example of FIG. 1, in particular, the first conversion switch circuit SWd1 controls electrical connection based on the digital signal DIN such that the other end of the first conversion current source Md1 is electrically connected to the output terminal TOUT or the ground. The n-th conversion switch circuit SWdn is identical in configuration to the first conversion switch circuit SWd1.

Similarly, the n-th conversion switch circuit SWdn is disposed between the other end of the n-th conversion current source Mdn and the output terminal TOUT to control electrical connection between the n-th conversion current source Mdn and the output terminal based on the digital signal DIN.

Moreover, one end of the first correction current source Mc1 is connected to the power supply to output a first correction current in response to the detection signals Vg1 to Vgn.

Similarly, one end of the n-th correction current source Mcn is connected to the power supply to output an n-th correction current in response to the detection signals Vg1 to Vgn.

For example, the value of the first correction current is equal to the value of the n-th correction current.

The first correction switch circuit SWc1 is disposed between the other end of the first correction current source Mc1 and the output terminal TOUT to control electrical connection between the first correction current source Mc1 and the output terminal TOUT based on the digital signal DIN.

In the example of FIG. 1, in particular, the first correction switch circuit SWc1 controls electrical connection based on the digital signal DIN such that the other end of the first correction current source Mc1 is electrically connected to the output terminal TOUT. The n-th correction switch circuit SWcn is identical in configuration to the first correction switch circuit SWc1.

Similarly, the n-th correction switch circuit SWcn electrically connects the other end of the n-th correction current source Mcn and the output terminal TOUT based on the digital signal DIN.

As will be described in the subsequent embodiment, the digital/analog converter circuit 100 may include a decoder that controls the conversion switch circuits SWd1 to SWdn or the n correction switch circuits SWc1 to SWcn based on signals obtained by decoding the detection signals Vg1 to Vgn.

As will be described in the subsequent embodiment, the digital/analog converter circuit 100 may include a selector that selects the detection signals Vg1 to Vgn supplied to the correction current sources Mc1 to Mcn, based on signals obtained by decoding the detection signals Vg1 to Vgn by means of a decoder. In other words, the effect of the present embodiment can be obtained even if the number of correction current sources is equal to that of the detection signals.

As described above, in the digital/analog converter circuit 100, the main unit X outputs the current Idac to the output terminal TOUT in response to the digital signal DIN. The correcting section Y outputs the current Ical to the output terminal TOUT in response to the digital signal DIN and the detection signals Vg1 to Vgn.

The passage of the output current Ioutp (the current Idac+the current Ical) through the output resistor ROUT outputs the output voltage (analog signal) VOUTP from the output terminal TOUT.

In other words, the output voltage (analog signal) VOUTP is corrected by the detection signals Vg1 to Vgn outputted from the error current detecting unit ID.

Thus, in the event of fluctuations in power supply voltage, process fluctuations, and temperature fluctuations, the output current Ioutp can be selectively corrected in response to the inputted digital signal DIN so as to compensate for the influence of an error current of the current source, the error current being caused by fluctuations in the output voltage of the digital/analog converting unit DAC. In other words, the influence of a current error caused by fluctuations in output voltage can be reduced.

As described above, the digital/analog converter circuit according to the first embodiment can improve the linearity of the input/output characteristics of a DAC in the event of fluctuations in power supply voltage, process fluctuations, and temperature fluctuations.

### Second Embodiment

The first embodiment described the basic configuration of the digital/analog converter circuit.

In a second embodiment, a more specific example of the configuration and operating characteristics of a digital/analog converter will be described below. In the following example, n is 3 but may include other figures.

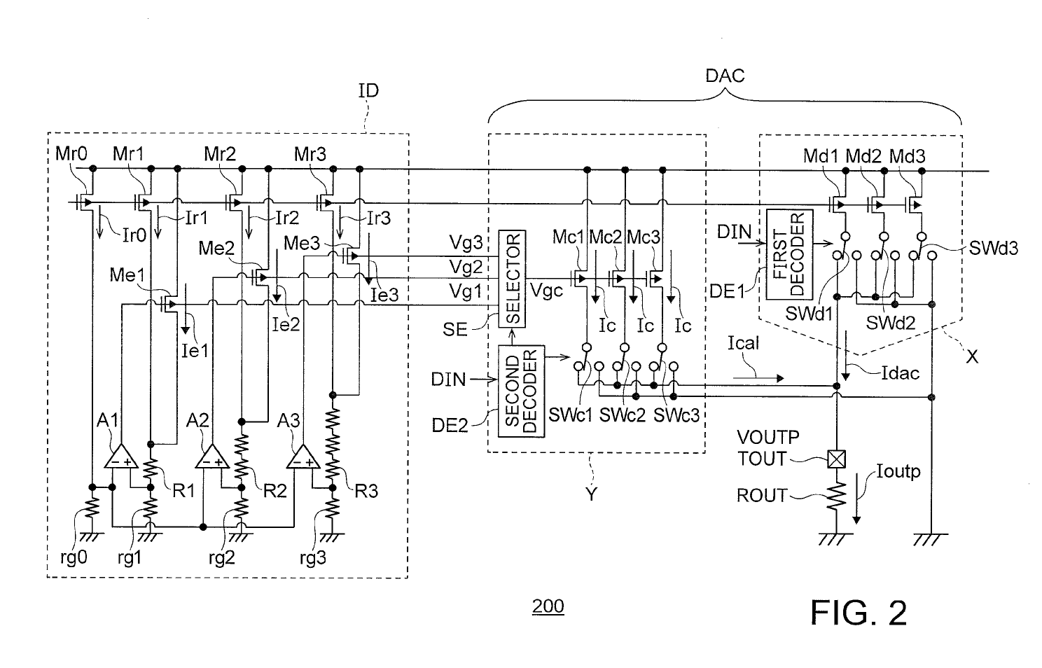

FIG. 2 shows a configuration example of a digital/analog converter circuit 200 according to the second embodiment. In FIG. 2, the same reference numerals as in FIG. 1 indicate the same configurations as in the first embodiment.

As shown in FIG. 2, the digital/analog converter circuit 200 includes a digital/analog converting unit DAC and an error current detecting unit ID as in the first embodiment.

As in the first embodiment, the digital/analog converting unit DAC receives a digital signal DIN and outputs an output current Ioutp to an output terminal TOUT in response to the digital signal DIN.

As shown in FIG. 2, the digital/analog converting unit DAC includes a main unit X, a correcting section Y, and an output resistor ROUT as in the first embodiment.

The main unit X includes first to third conversion current sources Md1 to Md3, first to third conversion switch circuits SWd1 to SWd3, and a first decoder DE1.

The main unit X receives the digital signal DIN and outputs a current Idac to the output terminal TOUT in response to the digital signal DIN.

The correcting section Y includes first to third correction current sources Mc1 to Mc3, first to third correction switch circuits SWc1 to SWc3, a second decoder DE2, and a selector SE.

The correcting section Y receives the digital signal DIN and outputs a current Ical to the output terminal TOUT in response to the digital signal DIN and detection signals Vg1 to Vg3.

In this configuration, one end of the first conversion current source Md1 is connected to a power supply to output a first conversion current.

As shown in FIG. 2, the first conversion current source Md1 is, for example, a first conversion MOS transistor that has one end (source) connected to the power supply, the other end (drain) connected to the first conversion switch circuit SWd1, and its gate connected to the gate of a reference MOS transistor (reference current source Mr0), which will be described later.

One end of the second conversion current source Md2 is connected to the power supply to output a second conversion current obtained by performing a current mirror operation on the first conversion current.

As shown in FIG. 2, the second conversion current source Md2 is, for example, a second conversion MOS transistor that has one end (source) connected to the power supply, the other end (drain) connected to the second conversion switch circuit SWd2, and its gate connected to the gate of the first conversion MOS transistor.

The third conversion current source Md3 is identical in configuration to the second conversion current source Md2.

The first to third conversion switch circuits SWd1 to SWd3 electrically connect the other ends of the first to third conversion current sources Md1 to Md3 to the output terminal TOUT based on the digital signal DIN.

In the example of FIG. 2, in particular, the first to third conversion switch circuits SWd1 to SWd3 control electrical connection based on the digital signal DIN such that the other ends of the first to third conversion current sources Md1 to Md3 are electrically connected to the output terminal TOUT or the ground.

The first conversion MOS transistor is identical in size to the second and third conversion MOS transistor.

Moreover, one ends of the first to third correction current sources Mc1 to Mc3 are connected to the power supply to output first to third correction currents Ic in response to the detection signals Vg1 to Vg3.

The first to third correction current sources Mc1 to Mc3 are first to third correction MOS transistors that have one ends (sources) connected to the power supply, the other ends (drains) connected to the respective first to third correction switch circuits SWc1 to SWc3, and its gates receiving a detection signal Vgc outputted from the selector SE.

For example, the value of the first correction current Ic is equal to the values of the second and third correction currents Ic.

The first to third correction switch circuits SWc1 to SWc3 are disposed between the other ends of the first to third correction current sources Mc1 to Mc3 and the output terminal TOUT to control electrical connection between the first to third correction current sources Mc1 to Mc3 and the output terminal TOUT based on the digital signal DIN.

In the example of FIG. 2, in particular, the first correction switch circuits SWc1 to SWc3 control electrical connection based on the digital signal DIN such that the other ends of the first to third correction current sources Mc1 to Mc3 are electrically connected to the output terminal TOUT or the ground.

The first decoder DE1 controls the first to third conversion switch circuits SWd1 to SWd3 based on information obtained by decoding the digital signal DIN.

The second decoder DE2 controls the first to third correction switch circuits SWc1 to SWc3 based on information obtained by decoding the digital signal DIN.

For example, the first decoder DE1 controls the first conversion switch circuit SWd1 based on the digital signal DIN so as to electrically connect the other end of the first conversion current source Md1 and the output terminal TOUT. In this case, the second decoder DE2 controls the first correction switch circuit SWc1 based on the digital signal DIN so as to electrically connect the other end of the first correction current source Mc1 and the output terminal TOUT.

The first decoder DE1 controls the first and second conversion switch circuits SWd1 and SWd2 based on the digital signal DIN so as to electrically connect the other ends of the first and second conversion current sources Md1 and Md2 and the output terminal TOUT. In this case, the second decoder DE2 controls the first and second correction switch circuits SWc1 and SWc2 based on the digital signal DIN so as to electrically connect the other ends of the first and second correction current sources Mc1 and Mc2 and the output terminal TOUT.

The first decoder DE1 controls the first to third conversion switch circuits SWd1 to SWd3 based on the digital signal DIN so as to electrically connect the other ends of the first to third conversion current sources Md1 to Md3 and the output terminal TOUT. In this case, the second decoder DE2 controls the first to third correction switch circuits SWc1 to SWc3 based on the digital signal DIN so as to electrically connect the other ends of the first to third correction current sources Mc1 to Mc3 and the output terminal TOUT.

Specifically, the first to third correction switch circuits SWc1 to SWc3 perform switching operations in synchronization with the first to third conversion switch circuits SWd1 to SWd3.

The selector SE is controlled by the second decoder DE based on the digital signal DIN so as to select one of the first detection signal Vg1, the second detection signal Vg2, and the third detection signal Vg3 as the detection signal Vgc.

Specifically, in the case where one of the conversion current sources is electrically connected to the output terminal TOUT and the other conversion current sources are electrically connected to the ground, the selector SE selects the first detection signal Vg1 and outputs the signal as the detection signal Vgc.

For example, in the case where the first conversion current source Md1 is electrically connected to the output terminal TOUT via the first conversion switch circuit SWd1 based on the digital signal DIN in the main unit X while the second and third conversion current sources Md2 and Md3 are electrically connected to the ground, the selector SE selects the first detection signal Vg1 and outputs the signal as the detection signal Vgc.

In the case where two of the conversion current sources are electrically connected to the output terminal TOUT and the other conversion current source is electrically connected to the ground, the selector SE selects the second detection signal Vg2 and outputs the signal as the detection signal Vgc.

For example, in the case where the first and second conversion current sources Md1 and Md2 are electrically connected to the output terminal TOUT via the first and second conversion switch circuits SWd1 and SWd2 based on the digital signal DIN in the main unit X while the third conversion current source Md3 is electrically connected to the ground, the selector SE selects the second detection signal Vg2 and outputs the signal as the detection signal Vgc.

In the case where the three conversion current sources are electrically connected to the output terminal TOUT, the selector SE selects the third detection signal Vg3 and outputs the signal as the detection signal Vgc.

For example, in the case where the first to third conversion current sources Md1 to Md3 are electrically connected to the output terminal TOUT via the first to third conversion switch circuits SWd1 to SWd3 based on the digital signal DIN in the main unit X, the selector SE selects the third detection signal Vg3 and outputs the signal as the detection signal Vgc.

In other words, the selector SE determines the detection signal Vgc according to the number of conversion current sources electrically connected to the output terminal TOUT in the main unit X. The connection between the conversion current source and the output terminal TOUT is controlled by the conversion switch circuit based on a control signal obtained by decoding the digital signal DIN by means of the first decoder DE1.

As shown in FIG. 2, the error current detecting unit ID outputs the detection signals Vg1 to Vg3 to the digital/analog converting unit DAC to correct the output current Ioutp.

As shown in FIG. 2, the error current detecting unit ID includes, for example, a reference current source Mr0, a reference resistor rg0, a first detection current source Mr1, a second detection current source Mr2, a third detection current source Mr3, a first error resistor R1, a second error resistor R2, a third error resistor R3, a first detection resistor rg1, a second detection resistor rg2, a third detection resistor rg3, a first error current source Me1, a second error current source Me2, a third error current source Me3, a first error amplifier circuit A1, a second error amplifier circuit A2, and a third error amplifier circuit A3.

One end of the reference current source Mr0 is connected to the power supply to output a reference current. As shown in FIG. 2, the reference current source Mr0 is, for example, a reference MOS transistor having one end (source) connected to the power supply and the other end (drain) connected to one end of the first reference resistor rg0.

One end of the reference resistor rg0 is connected to the other end of the reference current source Mr0 while the other end of the reference resistor rg0 is connected to the ground.

One end of the first detection current source Mr1 is connected to the power supply to output a current Ir1 obtained by performing a current mirror operation on a reference current Ir0 that passes through the reference current source Mr0.

As shown in FIG. 2, the first detection current source Mr1 is, for example, a first detection MOS transistor that has one end (source) connected to the power supply, the other end (drain) connected to one end of the first error resistor R1, and its gate connected to the gate of a reference MOS transistor.

One end of the second detection current source Mr2 is connected to the power supply to output a current Ir2 obtained by performing a current mirror operation on the reference current Ir0 that passes through the reference current source Mr0.

As shown in FIG. 2, the second detection current source Mr2 is, for example, a second detection MOS transistor that has one end (source) connected to the power supply, the other end (drain) connected to one end of the second error resistor R2, and its gate connected to the gate of the reference MOS transistor.

One end of the third detection current source Mr3 is connected to the power supply to output a current Ir3 obtained by performing a current mirror operation on the reference current Ir0 that passes through the reference current source Mr0.

As shown in FIG. 2, the third detection current source Mr3 is, for example, a third detection MOS transistor that has one end (source) connected to the power supply, the other end (drain) connected to one end of the third error resistor R2, and its gate connected to the gate of the reference MOS transistor.

The size of the reference MOS transistor is set identical to those of the first to third detection MOS transistors.

The resistance value of the second error resistor R2 is set larger than that of the first error resistor R1. For example, the resistance value of the second error resistor R2 is set twice as large as the resistance value of the first error resistor R1.

The resistance value of the third error resistor R3 is set larger than that of the first error resistor R1. For example, the resistance value of the third error resistor R3 is three times as large as that of the third error resistor R3.

One ends of the first to third detection resistors rg1 to rg3 are respectively connected to the other ends of the first to third error resistors R1 to R3 while the other ends of the first to third detection resistors rg1 to rg3 are connected to the ground. The first to third detection resistors rg1 to rg3 have the same resistance value as the reference resistor rg0.

The first error amplifier circuit A1 outputs, as the first detection signal Vg1, a voltage obtained by amplifying an error between a voltage on one end of the reference resistor rg0 and a voltage on one end of the first detection resistor rg1.

In the example of FIG. 2, in particular, the inverting input terminal of the first error amplifier circuit A1 is connected to one end of the reference resistor rg0 while the non-inverting input terminal of the first error amplifier circuit A1 is connected to one end of the first detection resistor rg1 to output the first detection signal Vg1 to the selector SE.

The second error amplifier circuit A2 outputs, as the second detection signal Vg2, a voltage obtained by amplifying an error between a voltage on one end of the reference resistor rg0 and a voltage on one end of the second detection resistor rg2.

In the example of FIG. 2, in particular, the inverting input terminal of the second error amplifier circuit A2 is connected to one end of the reference resistor rg0 while the non-inverting input terminal of the second error amplifier circuit A2 is connected to one end of the second detection resistor rg2 to output the second detection signal Vg2 to the selector SE.

The third error amplifier circuit A3 outputs, as the third detection signal Vg3, a voltage obtained by amplifying an error between a voltage on one end of the reference resistor rg0 and a voltage on one end of the third detection resistor rg3.

In the example of FIG. 2, in particular, the inverting input terminal of the third error amplifier circuit A3 is connected to one end of the reference resistor rg0 while the non-inverting input terminal of the third error amplifier circuit A3 is connected to one end of the third detection resistor rg3 to output the third detection signal Vg3 to the selector SE.

One end of the first error current source Me1 is connected to the power supply while the other end of the first error current source Me1 is connected to one end of the first error resistor R1 to output an error current Ie1 in response to the first detection signal Vg1.

One end of the second error current source Me2 is connected to the power supply while the other end of the second error current source Me2 is connected to one end of the second error resistor R2 to output an error current Ie2 in response to the second detection signal Vg2.

One end of the third error current source Me3 is connected to the power supply while the other end of the third error current source Me3 is connected to one end of the third error resistor R3 to output an error current Ie3 in response to the third detection signal Vg3.

As shown in FIG. 2, the first to third error current sources Me1 to Me3 are, for example, first to third error MOS transistors that have one ends (source) connected to the power supply, the other ends (drains) connected to one ends of the first to third error resistors R1 to R3, and the first to third detection signals Vg1 to Vg3 are surprised to its gates.

For example, the sizes of the first to third error MOS transistors Me1 to Me3 are set identical to those of the first to third correction MOS transistors Mc1 to Mc3.

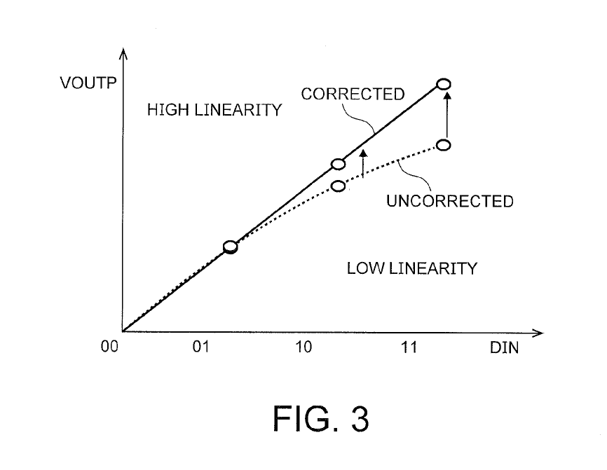

The operating characteristics of the digital/analog converter circuit 200 configured as illustrated in FIG. 2 will be described below. In this example, it is assumed that the digital signal DIN is a 2-bit signal. FIG. 3 shows an example of the relationship between the digital signal DIN of the digital/analog converter circuit 200 in FIG. 2 and an output voltage VOUTP that is an analog signal.

(A) Digital signal DIN=(00)

In this case, for example, the first decoder DE1 controls the first to third conversion switch circuits SWd1 to SWd3 so as to electrically connect the other ends of the first to third conversion current sources Md1 to Md3 and the ground. Furthermore, the second decoder DE2 controls the first to third correction switch circuits SWc1 to SWc3 so as to electrically connect the other ends of the first to third correction current sources Mc1 to Mc3 and the ground.

Thus, the current Idac(00) passing through the output terminal TOUT from the main unit X is 0 while the current Ical(00) passing through the output terminal TOUT from the correcting section Y is 0. In other words, the output current Ioutp is 0.

Thus, the output voltage VOUTP(00) is expressed as below:

Output voltage VOUTP(00)=output resistor ROUT×0=0

(B) Digital signal DIN=(01)

In this case, for example, the first decoder DE1 controls the first conversion switch circuit SWd1 so as to electrically connect the other end of the first conversion current source Md1 and the output terminal TOUT. Furthermore, the second decoder DE2 controls the first correction switch circuit SWc1 so as to electrically connect the other end of the first correction current source Mc1 and the output terminal TOUT.

At this point, the selector SE selects the first detection signal Vg1 and outputs the signal as the detection signal Vgc.

Thus, in the case where the digital signal DIN is (01), the current Idac(01) passes through the output terminal TOUT from the main unit X while the current Ical(01) passing through the output terminal TOUT from the correcting section Y is Ic (=Ie1). In other words, the output current Ioutp is expressed as below:

Output current Ioutp=Idac(01)+Ic

Thus, the output voltage VOUTP(01) is expressed as below:

Output voltage VOUTP(01)=Output resistor ROUT×(Idac(01)+Ic)

(C) Digital signal DIN=(10) In this case, for example, the first decoder DE1 controls the first and second conversion switch circuits SWd1 and SWd2 so as to electrically connect the other ends of the first and second conversion current sources Md1 and Md2 and the output terminal TOUT. Furthermore, the second decoder DE2 controls the first and second correction switch circuits SWc1 and SWc2 based on the digital signal DIN so as to electrically connect the other ends of the first and second correction current sources Mc1 and Mcg and the output terminal TOUT.

At this point, the selector SE selects the second detection signal Vg2 and outputs the signal as the detection signal Vgc.

Thus, the current Idac(10) passes through the output terminal TOUT from the main unit X and the current Ical(10) passing through the output terminal TOUT from the correcting section Y is expressed by Ic×2(=Ie2×2). Hence, the output current Ioutp is expressed as follows:

Output current Ioutp=Idac(10)+Ic×2

Hence, the output voltage VOUTP(10) is expressed as follows:

Output voltage VOUTP(10)=Output resistor ROUT×(Idac(10)+Ic×2)

(D) Digital signal DIN=(11)

In this case, for example, the first decoder DE1 controls the first to third conversion switch circuits SWd1 to SWd3 so as to electrically connect the other ends of the first to third conversion current sources Md1 to Md3 and the output terminal TOUT. Moreover, the second decoder DE2 controls the first to third correction switch circuits SWc1 to SWc3 so as to electrically connect the other ends of the first to third correction current sources Mc1 to Mc3 and the output terminal TOUT.

At this point, the selector SE selects the third detection signal Vg3 and outputs the signal as the detection signal Vgc.

Thus, the current Idac(11) passes through the output terminal TOUT from the main unit X and the current Ical(11) passing through the output terminal TOUT from the correcting section Y is expressed as Ic×3 (=Ie3×3). In other words, the output current Ioutp is expressed as follows:

Output current Ioutp=Idac(11)+Ic×3

Thus, the output voltage (analog signal) VOUTP(11) is expressed as below:

Output voltage(analog signal)VOUTP(11)=output resistor ROUT×(Idac(11)+Ic×3)

As described above, the digital/analog converter circuit 200 operating in response to the digital signal DIN corrects the output voltage VOUTP, which is an analog signal, to a higher voltage (FIG. 3).

In this configuration, the reference MOS transistor (reference current source) Mr0, the first detection MOS transistor (first detection current source) Mr1, a second detection MOS transistor (second detection current source) Mr2, and a third detection MOS transistor (third detection current source) Mr3 are all identical in size. Hence, a current mirror operation applies an equal current to the transistors.

Variations in resistance value among the resistors R1 to R3 connected to the drains of the MOS transistors Mr0 to Mr3 cause variations of a drain to source voltage Vds among the MOS transistors Mr0 to Mr3.

In other words, an error occurs among the currents Ir0 to Ir3 passing through the MOS transistors Mr0 to Mr3. Specifically, the currents have the following relationship:

Reference current Ir0>Current Ir1>Current Ir2>Current Ir3

This can reproduce a channel length modulation effect.

The operations of the first to third error amplifier circuits A1 to A3 automatically adjust the currents Ie1 to Ie3 so as to equalize the potentials of the resistors rg0 to rg3.

In other words, the reference current Ir0 is expressed as below:

Reference current Ir0=Current Ir1+Current Ie1=Current Ir2+Current Ie2=Current Ir3+Current Ie3

As described above, a current error caused by an insufficient resistance of the MOS transistor can be compensated by a current corresponding to the drain to source voltage Vds, enabling an automatic correction. This can reduce the influence of error current fluctuations that are caused by fluctuations in power supply voltage, process fluctuations, and temperature fluctuations.

The digital/analog converter circuit 200 according to the second embodiment can improve linearity in the event of fluctuations in power supply voltage, process fluctuations, and temperature fluctuations.

The digital/analog converter circuit according to the second embodiment can particularly operate at a low power supply voltage. Thus, the current source does not need a cascode connection for a high output resistance. In other words, the area of the MOS transistor for the current source can be reduced.

### Third Embodiment

The second embodiment described a configuration example in which the error current detecting unit ID outputs the multiple detection signals selected by the selector SE of the digital/analog converting unit DAC.

A third embodiment will describe a configuration example in which an error current detecting unit ID outputs a single detection signal and a selector is omitted.

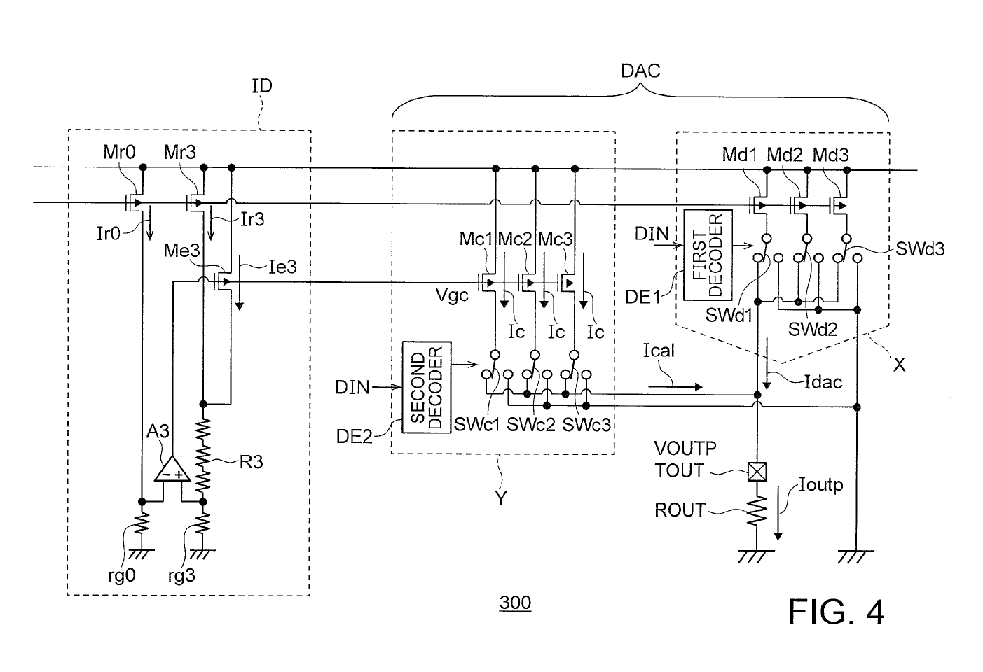

FIG. 4 shows a configuration example of a digital/analog converter circuit 300 according to the third embodiment. In FIG. 4, the same reference numerals as in FIG. 2 indicate the same configurations as in the second embodiment and the explanation thereof is omitted.

As shown in FIG. 4, the digital/analog converter circuit 300 includes a digital/analog converting unit DAC and the error current detecting unit ID as in the second embodiment.

As shown in FIG. 4, the error current detecting unit ID outputs a detection signal Vgc(Vg3) to the digital/analog converting unit DAC to correct an output current Ioutp.

As shown in FIG. 4, the error current detecting unit ID includes, for example, a reference current source Mr0, a reference resistor rg0, a third detection current source Mr3, a third error resistor R3, a third detection resistor rg3, a third error current source Me3, and a third error amplifier circuit A3.

Unlike in the second embodiment, first and second detection current sources Mr1 and Mr2, first and second error resistors R1 and R2, first and second detection resistors rg1 and rg2, first and second error current sources Me1 and Me2, and first and second error amplifier circuits A1 and A2 are omitted in the error current detecting unit ID of the third embodiment.

A correcting section Y includes first to third correction current sources Mc1 to Mc3, first to third correction switch circuits SWc1 to SWc3, and a second decoder DE2.

Unlike in the second embodiment, a selector SE is omitted in the correcting section Y of the third embodiment. The detection signal Vgc(Vg3) outputted from the third error amplifier circuit A3 is directly inputted to the first to third correction current sources Mc1 to Mc3.

In the digital/analog converter circuit 300, a selector is omitted and the error current detecting unit ID outputs a detection signal unlike in the digital/analog converter circuit 200 of the second embodiment.

This allows the digital/analog converter circuit 300 to have a smaller circuit area than the digital/analog converter circuit 200 of the second embodiment.

Other configurations of the digital/analog converter circuit 300 are identical to those of the second embodiment.

The operations of the digital/analog converter circuit 300 configures as illustrated in FIG. 4 are similar to those of the second embodiment except for the omission of the operation of the selector SE.

The digital/analog converter circuit 300 operating in response to a digital signal DIN corrects an output voltage VOUTP, which is an analog signal, to a higher voltage.

This can reduce the influence of error current fluctuations in the event of fluctuations in power supply voltage, process fluctuations, and temperature fluctuations.

As described above, the digital/analog converter circuit 300 according to the present embodiment can improve linearity at a low power supply voltage with a smaller circuit area.

### Fourth Embodiment

The second embodiment described a configuration example in which the digital/analog converting unit DAC includes the main unit X and the correcting section Y.

A fourth embodiment will describe a configuration example of the sharing of a main unit X and a correcting section Y.

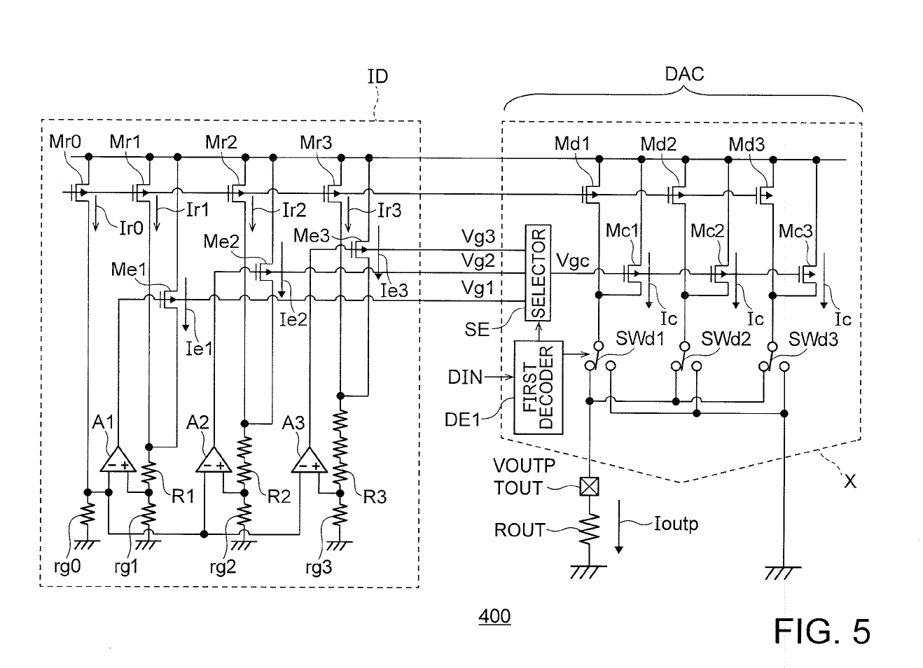

FIG. 5 shows a configuration example of a digital/analog converter circuit 400 according to the fourth embodiment. In FIG. 5, the same reference numerals as in FIG. 2 indicate the same configurations as in the second embodiment and the explanation thereof is omitted.

As shown in FIG. 5, the digital/analog converter circuit 400 includes a digital/analog converting unit DAC and an error current detecting unit ID as in the second embodiment.

The digital/analog converting unit DAC in FIG. 5 includes the main unit X and an output resistor ROUT.

The main unit X includes first to third conversion current sources Md1 to Md3, first to third conversion switch circuits SWd1 to SWd3, first to third correction current sources Mc1 to Mc3, a first decoder DE1, and a selector SE.

The main unit X receives a digital signal DIN, outputs a current Idac to an output terminal TOUT in response to the digital signal DIN, and outputs a current Ical to the output terminal TOUT in response to the digital signal DIN and detection signals Vg1 to Vg3.

As shown in FIG. 5, the other end of the first correction current source Mc1 is connected to the other end of the first conversion current source Md1.

The other end of the second correction current source Mc2 is connected to the other end of the second conversion current source Md2.

The other end of the third correction current source Mc3 is connected to the other end of the third conversion current source Md3.

The first to third correction switch circuits SWc1 to SWc3 and the first to third conversion switch circuits SWd1 to SWd3 in FIG. 2 are shared as the first to third conversion switch circuits SWd1 to SWd3 in FIG. 5.

The first decoder DE1 and the second decoder DE2 in FIG. 2 are shared as the first decoder DE1 in FIG. 5.

In the fourth embodiment, as above described, the main unit X and the correcting section Y are shared. This allows the digital/analog converter circuit 400 to have a smaller circuit area than the digital/analog converter circuit 200 of the second embodiment.

Other configurations of the digital/analog converter circuit 400 are identical to those of the second embodiment.

The operations of the digital/analog converter circuit 400 configured as illustrated in FIG. 5 are similar to those of the second embodiment except for the shared operations of the first decoder DE1 and the second decoder DE2.

The digital/analog converter circuit 400 operating in response to the digital signal DIN corrects an output voltage VOUTP, which is an analog signal, to a higher voltage.

This can reduce the influence of error current fluctuations in the event of fluctuations in power supply voltage, process fluctuations, and temperature fluctuations.

As described above, the digital/analog converter circuit 400 according to the fourth embodiment can improve linearity at a low power supply voltage as in the first embodiment.

### Fifth Embodiment

A fifth embodiment will describe a configuration example of a combination of the configuration of the third embodiment and the configuration of the fourth embodiment.

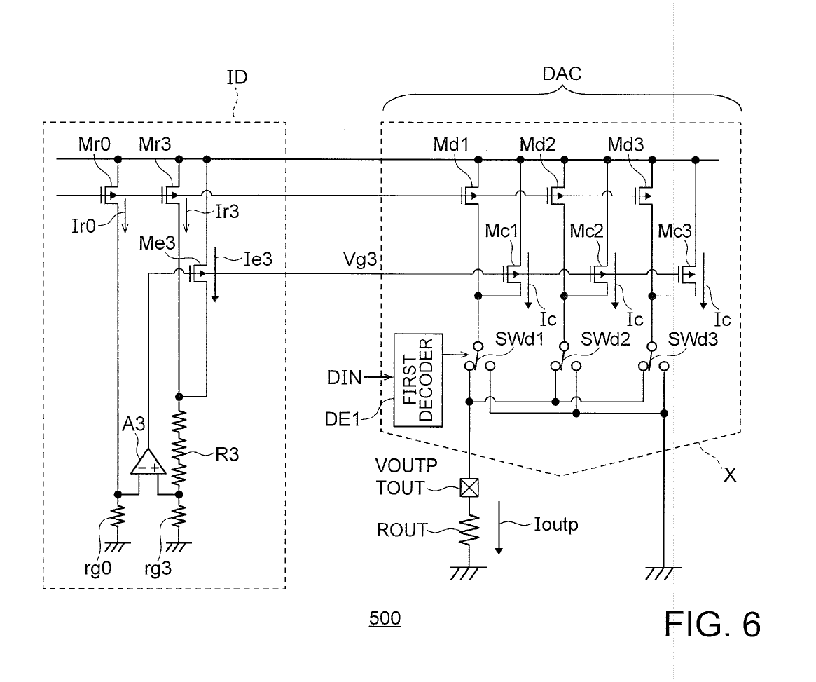

FIG. 6 shows a configuration example of a digital/analog converter circuit 500 according to a fifth embodiment. In FIG. 6, the same reference numerals as in FIGS. 4 and 5 indicate the same configurations as in the third and fourth embodiments and the explanation thereof is omitted.

As shown in FIG. 6, the digital/analog converter circuit 500 includes a digital/analog converting unit DAC and an error current detecting unit ID as in the third and fourth embodiments.

The error current detecting unit ID outputs a detection signal Vgc(Vg3) to the digital/analog converting unit DAC to correct an output current Ioutp.

As in the third embodiment, the error current detecting unit ID includes a reference current source Mr0, a reference resistor rg0, a third detection current source Mr3, a third error resistor R3, a third detection resistor rg3, a third error current source Me3, and a third error amplifier circuit A3.

As in the fourth embodiment, the digital/analog converting unit DAC includes a main unit X and an output resistor ROUT.

The main unit X includes first to third conversion current sources Md1 to Md3, first to third conversion switch circuits SWd1 to SWd3, first to third correction current sources Mc1 to Mc3, and a first decoder DE1.

In the fifth embodiment, a selector is omitted and the error current detecting unit ID outputs a detection signal. Furthermore, the main unit X and the correcting section Y are shared. This can further reduce the circuit area of the digital/analog converter circuit 500.

Other configurations of the digital/analog converter circuit 500 are similar to those of the third and fourth embodiments.

The operations of the digital/analog converter circuit 500 configured as illustrated in FIG. 6 are similar to those of the third and fourth embodiments except for the shared operations of the first decoder DE1 and the second decoder DE2 and the omission of the operation of the selector SE.

In other words, the digital/analog converter circuit 500 operating in response to the digital signal DIN corrects an output voltage VOUTP, which is an analog signal, to a higher voltage.

This can reduce the influence of error current fluctuations in the event of fluctuations in power supply voltage, process fluctuations, and temperature fluctuations.

As described above, the digital/analog converter circuit 500 according to the fifth embodiment can improve linearity in the event of fluctuations in power supply voltage, process fluctuations, and temperature fluctuations.

While certain embodiments have been described, these embodiments have been presented by way of example only, and are not intended to limit the scope of the inventions. Indeed, the novel methods and systems described herein may be embodied in a variety of other forms; furthermore, various omissions, substitutions and changes in the form of the methods and systems described herein may be made without departing from the spirit of the inventions. The accompanying claims and their equivalents are intended to cover such forms or modifications as would fall within the scope and spirit of the inventions.

What is claimed is:

1. A digital/analog converter circuit comprising:
a digital/analog converting unit that receives a digital signal and outputs an output current to an output terminal in response to the digital signal; and
an error current detecting unit that outputs a detection signal to the digital/analog converting unit, the detection signal correcting the output current,
the digital/analog converting unit including:
a first conversion current source that outputs a first conversion current with a first end connected to a power supply;
a second conversion current source that outputs a second conversion current with a first end connected to the power supply, the second conversion current being obtained by performing a current mirror operation on the first conversion current;
a first conversion switch circuit that controls electrical connection between a second end of the first conversion current source and the output terminal based on the digital signal;
a second conversion switch circuit that controls electrical connection between a second end of the second conversion current source and the output terminal based on the digital signal;
a first correction current source having a first end connected to the power supply, the first correction current source outputting a first correction current in response to the detection signal;
a second correction current source having a first end connected to the power supply, the second correction current source outputting a second correction current in response to the detection signal;
a first correction switch circuit that controls electrical connection between a second end of the first correction current source and the output terminal in synchronization with the first conversion switch circuit; and
a second correction switch circuit that controls electrical connection between a second end of the second correction current source and the output terminal in synchronization with the second conversion switch circuit.

2. The digital/analog converter circuit according to claim 1, further comprising an output resistor connected between the output terminal and ground.

3. The digital/analog converter circuit according to claim 1, wherein the first correction current has a value equal to a value of the second correction current.

4. The digital/analog converter circuit according to claim 1, wherein
the error current detecting unit includes:
a reference current source having a first end connected to the power supply and outputting a reference current;
a reference resistor having a first end connected to a second end of the reference current source and a second end connected to ground;
a detection current source having a first end connected to the power supply and outputting a current, the current being obtained by performing a current mirror operation on the reference current passing through the reference current source;
an error resistor having a first end connected to a second end of the first detection current source;
a detection resistor having a first end connected to a second end of the error resistor and a second end connected to the ground, the detection resistor having a resistance value equal to a resistance value of the reference resistor;
an error amplifier circuit that outputs, as a detection signal, a voltage obtained by amplifying an error between a voltage on the first end of the reference resistor and a voltage on the first end of the detection resistor; and
an error current source having a first end connected to the power supply and a second end connected to the first end of the error resistor, the error current source outputting an error current in response to the detection signal.

5. The digital/analog converter circuit according to claim 4, wherein the first correction current has a value equal to a value of the second correction current.

6. The digital/analog converter circuit according to claim 1, wherein the error current detecting unit includes:
a reference current source with a first end connected to the power supply and outputting a reference current;
a reference resistor having a first end connected to a second end of the reference current source and a second end connected to ground;
a first detection current source having a first end connected to the power supply and outputting a current, the current being obtained by performing a current mirror operation on the reference current passing through the reference current source;
a second detection current source having a first end connected to the power supply and outputting a current, the current being obtained by performing a current mirror operation on the reference current passing through the reference current source;
a first error resistor having a first end connected to a second end of the first detection current source;
a second error resistor having a first end connected to a second end of the second detection current source, the second error resistor having a resistance value larger than a resistance value of the first error resistor;
a first detection resistor having a first end connected to a second end of the first error resistor and a second end connected to the ground, the first detection resistor having a resistance value equal to a resistance value of the reference resistor;
a second detection resistor having a first end connected to a second end of the second error resistor and a second end connected to the ground, the second detection resistor having a resistance value equal to the resistance value of the reference resistor;
a first error amplifier circuit that outputs, as a first detection signal, a voltage obtained by amplifying an error between a voltage on the first end of the reference resistor and a voltage on the first end of the first detection resistor;
a second error amplifier circuit that outputs, as a second detection signal, a voltage obtained by amplifying an error between the voltage on the first end of the reference resistor and a voltage on the first end of the second detection resistor;
a first error current source having a first end connected to the power supply and a second end connected to the first end of the first error resistor, the first error current source outputting an error current in response to the first detection signal; and
a second error current source having a first end connected to the power supply and a second end connected to the first end of the second error resistor, the second error current source outputting an error current in response to the second detection signal, and
the digital/analog converting unit further includes a selector that selects one of the first detection signal and the second detection signal as the detection signal based on the digital signal.

7. The digital/analog converter circuit according to claim 6, wherein the first correction current has a value equal to a value of the second correction current.

8. The digital/analog converter circuit according to claim 6, wherein the reference current source is a reference MOS transistor having a first end connected to the power supply and a second end connected to the first end of the first reference resistor;
wherein the first detection current source is a first detection MOS transistor having a first end connected to the power supply, a second other end connected to the first end of the first error resistor, and a gate connected to the gate of a reference MOS transistor, and
wherein the second detection current source is a second detection MOS transistor having a first end connected to the power supply, a second end connected to the first end of the second error resistor, and a gate connected to the gate of the reference MOS transistor.

9. The digital/analog converter circuit according to claim 8, wherein a size of the reference MOS transistor is equal to a size of the first detection MOS transistor and a size of the second detection MOS transistor.

10. The digital/analog converter circuit according to claim 8, wherein the first correction current has a value equal to a value of the second correction current.

11. A digital/analog converter circuit comprising:
a digital/analog converting unit that receives a digital signal and outputs an output current to an output terminal in response to the digital signal; and
an error current detecting unit that outputs a detection signal to the digital/analog converting unit, the detection signal correcting the output current,
the digital/analog converting unit including:
a first conversion current source having a first end connected to a power supply and outputting a first conversion current;
a second conversion current source having a first end connected to the power supply and outputting a second conversion current, the second conversion current being obtained by performing a current mirror operation on the first conversion current;
a first conversion switch circuit that controls electrical connection between a second end of the first conversion current source and the output terminal based on the digital signal;
a second conversion switch circuit that controls electrical connection between a second end of the second conversion current source and the output terminal based on the digital signal;
a first correction current source having a first end connected to the power supply and a second end connected to the second end of the first conversion current source, the first correction current source outputting a first correction current in response to the detection signal; and
a second correction current source having a first end connected to the power supply and a second end connected to the second end of the second conversion current source, the second correction current source outputting a second correction current in response to the detection signal.

12. The digital/analog converter circuit according to claim 11, further comprising an output resistor connected between the output terminal and ground.

13. The digital/analog converter circuit according to claim 11, wherein the first correction current has a value equal to a value of the second correction current.

14. The digital/analog converter circuit according to claim 11, wherein
the error current detecting unit includes:
a reference current source that outputs a reference current having a first end connected to the power supply;
a reference resistor having a first end connected to a second end of the reference current source and a second end connected to ground;
a detection current source having a first end connected to the power supply and outputting a current, the current being obtained by performing a current mirror operation on the reference current passing through the reference current source;
an error resistor having a first end connected to a second end of the first detection current source;
a detection resistor having a first end connected to a second end of the error resistor and a second end connected to the ground, the detection resistor having a resistance value equal to a resistance value of the reference resistor;
an error amplifier circuit that outputs, as a detection signal, a voltage obtained by amplifying an error between a voltage on the first end of the reference resistor and a voltage on the first end of the detection resistor; and
an error current source having a first end connected to the power supply and a second end connected to the first end of the error resistor, the error current source outputting an error current in response to the detection signal.

15. The digital/analog converter circuit according to claim 14, wherein the first correction current has a value equal to a value of the second correction current.

16. The digital/analog converter circuit according to claim 11, wherein the error current detecting unit includes:
a reference current source that outputs a reference current having a first end connected to the power supply;
a reference resistor having a first end connected to a second end of the reference current source and a second end connected to ground;
a first detection current source having a first end connected to the power supply and outputting a current, the current being obtained by performing a current mirror operation on the reference current passing through the reference current source;
a second detection current source having a first end connected to the power supply and outputting a current, the current being obtained by performing a current mirror operation on the reference current passing through the reference current source;
a first error resistor having a first end connected to a second end of the first detection current source;
a second error resistor having a first end connected to a second end of the second detection current source, the second error resistor having a resistance value larger than a resistance value of the first error resistor;
a first detection resistor having a first end connected to a second end of the first error resistor and a second end connected to the ground, the first detection resistor having a resistance value equal to a resistance value of the reference resistor;
a second detection resistor having a first end connected to a second end of the second error resistor and a second end connected to the ground, the second detection resistor having a resistance value equal to the resistance value of the reference resistor;
a first error amplifier circuit that outputs, as a first detection signal, a voltage obtained by amplifying an error between a voltage on the first end of the reference resistor and a voltage on the first end of the first detection resistor;
a second error amplifier circuit that outputs, as a second detection signal, a voltage obtained by amplifying an error between the voltage on the first end of the reference resistor and a voltage on the first end of the second detection resistor;
a first error current source having a first end connected to the power supply and a second end connected to the first end of the first error resistor, the first error current source outputting an error current in response to the first detection signal; and
a second error current source having a first end connected to the power supply and a second end connected to the first end of the second error resistor, the second error current source outputting an error current in response to the second detection signal, and
the digital/analog converting unit further includes a selector that selects one of the first detection signal and the second detection signal as the detection signal based on the digital signal.

17. The digital/analog converter circuit according to claim 16, wherein the first correction current has a value equal to a value of the second correction current.

18. The digital/analog converter circuit according to claim 16, wherein the reference current source is a reference MOS transistor having a first end connected to the power supply and a second end connected to the first end of the first reference resistor;
wherein the first detection current source is a first detection MOS transistor having a first end connected to the power supply, a second other end connected to the first end of the first error resistor, and a gate connected to the gate of a reference MOS transistor, and
wherein the second detection current source is a second detection MOS transistor having a first end connected to the power supply, a second end connected to the first end of the second error resistor, and a gate connected to the gate of the reference MOS transistor.

19. The digital/analog converter circuit according to claim 18, wherein a size of the reference MOS transistor is equal to a size of the first detection MOS transistor and a size of the second detection MOS transistor.

20. The digital/analog converter circuit according to claim 18, wherein the first correction current has a value equal to a value of the second correction current.
